(19) United States
(12) Patent Application Publication
(10) Pub. No.: US 2003/0062924 A1
(43) Pub. Date: Apr. 3, 2003

(54) Voltage translation circuit using a controlled transmission PMOS transistor

(76) Inventor: David C. Wyland, Morgan Hill, CA (US)

Correspondence Address: SCHNECK & SCHNECK, P.O. BOX 2-E, SAN JOSE, CA, 95109-0005, US

(21) Appl. No.: 09/968,640

(22) Filed: Sep. 28, 2001

(51) Int. Cl. H03K 19/0175

(52) U.S. Cl. 326/88

(57) ABSTRACT

Disclosed is a voltage translation circuit 400 that can translate different voltage levels (transmit logics between circuits operating at different voltage levels) faster but consumes less energy than that of prior art. The voltage translation circuit 400 of the present invention utilizes two transistors (transmission NMOS transistor 160 and transmission PMOS transistor 200) in parallel and in combination with a bootstrap circuit 195 consisting of a pull-up control CMOS inverter 170, 180 and a pull-up PMOS transistor 190. When node 140 rises from 0V to 3V (LVDD, i.e. logic 1), transmission PMOS transistor 200 helps to raise the input voltage to pull-up control CMOS inverter 170, 180 faster and therefore helps to turn on pull-up PMOS transistor 190 faster and hence raise the voltage of node 155 faster. This in turn helps turn off PMOS transistor 170 sooner, and hence stop the transition current going through transistors 170 and 180 sooner. Pull-up PMOS transistor 190 being turned on faster helps pull node 155 up to 5V (logic 1) faster.

### TECHNICAL FIELD

The present invention relates to voltage translation circuits, and more particularly to a circuit that can quickly translate logic levels with low power consumption.

### BACKGROUND ART

Advanced CMOS circuits use low operating voltages, such as 1.8 volts (V), while many other circuits operate at higher voltages, such as 3.6V and even 5V. One of the key challenges for advanced CMOS designs is the ability to interface low voltage advanced CMOS circuits to circuits operating at higher voltages. To operate devices having circuits that operate at different voltages, a voltage translation circuit is necessary to change one level of the operating voltage to another level. Suppose the voltage translation circuit couples an output of a first circuit operating at 3V to an input of a second circuit operating at 5V. When the output of the first circuit is 0V, the voltage translation circuit provides 0V to the input of the second circuit; when the output of the first circuit is 3V, the voltage translation provides 5V to the input of the second circuit. In that way, the second circuit can be compatible with the first circuit even though they operate at two different voltage levels, namely 3V and 5V. If the first and second circuits were coupled directly to each other without the voltage translation circuit such that the output of the first circuit is directly connected to the input of the second circuit, the second circuit will not be able to interpret whether a 3V level at the output of the first circuit means a logic 0 or a logic 1. Translating a logic 0 at the output of the first circuit to a logic 0 at the input of the second circuit can be simply done with a piece of wire. But, translating a logic 1 at the output of the first circuit (3V) to a logic 1 at the input of a second circuit (5V) is much more complicated. Therefore, a voltage translation circuit is necessary.

FIG. 1 shows a circuit portion 100 of the voltage translation circuit disclosed in FIG. 1 of U.S. Pat. No. 5,568,065. The output of the first circuit (not shown) operating at 3V connects to node 130.1, and node 130.2 connects to the input of the second circuit (not shown) operating at 5V. Nodes 130.1 and 130.2 are coupled through an transmission NMOS transistor 130. The gate voltage of transmission NMOS transistor 130 is 3V (LVDD, i.e. low VDD). Node 130.2 connects to the input of a CMOS inverter consisting of an PMOS transistor 142 and an NMOS transistor 146. The source of PMOS transistor 142 is connected to a voltage level of 5V (HVDD, i.e., high VDD). The output of this inverter (node A) applies to the gate of a pull-up PMOS transistor 150. Pull-up PMOS transistor 150 has its source connected to node 130.2 and its drain connected to a voltage level of 5V (HVDD). The CMOS inverter 142,146 and pull-up PMOS transistor 150 form a bootstrap circuit.

FIG. 2 shows an alternative view of circuit portion 100 of FIG. 1. The basic operation of circuit portion 100 is that: when node 130.1 is 0V, node 130.2 is also 0V; when node 130.1 is 3V, node 130.2 is 5V. The voltage levels of 0V, 3V, and 5V are used for illustrative purposes. In practice, any other voltage levels may apply. This prior art circuit portion works as follows.

With reference to FIG. 2, when node 130.1 is 0V, NMOS transistor 130 is on and pulls node 130.2 down to 0V. Inverter 142,146 makes node A 5V; therefore, PMOS transistor 150 is off. When node 130.1 rises to 3V (LVDD), node 130.2 follows node 130.1 because NMOS transistor 130 is still on. But, node 130.2 cannot go higher than 2V, one threshold voltage drop below gate voltage (assuming Vtn of NMOS 130 is 1V) or else the conducting channel through transmission NMOS transistor 130 would shut off. Inverter 142,146 is designed to change state at voltage level below 2V; therefore, node A becomes 0V and pull-up PMOS transistor 150 is turned on pulling node 130.2 past 2V and up to 5V. When node 130.2 increases past 2V and up to 5V, transmission NMOS transistor 130 turns off and remains off even when node 130.2 reaches 5V. When node 130.1 goes from 3V down to 0V, transmission NMOS transistor 130 turns on and pulls node 130.2 down. At some point, inverter 142,146 changes state and node A becomes 5V turning off PMOS transistor 150. With pull-up PMOS transistor 150 being off, node 130.2 follows 130.1 down to 0V. The function of inverter 142,146 is somewhat simplified in the description above. Its function will be described in detail below.

The prior art circuit portion 100 in FIG. 1 has the following disadvantage. When node 130.1 rises from 0V to 3V, node 130.2 follows node 130.1 but cannot exceed 2V due to a Vtn drop below the gate voltage of transmission NMOS transistor 130. Therefore, although NMOS transistor 146 turns on when node 130.2 exceeds its threshold voltage Vtn (_{—} 1V), PMOS transistor 142 is still on. There is a transition current going from 5V (LVDD, i.e. low VDD) to ground through transistors 142 and 146. Then, NMOS transistor 146 being turned on pulls node A down and this in turn turns on pull-up PMOS transistor 150. Then node 130.2 is pulled up to 5V by transistor 150 and this in turn shuts off PMOS transistor 142 and stop the transition current through transistor 142 and 146. So, the transition current exists for a while. Therefore, it is an object of the present invention to stop the transition current going through transistor 142 and 146 sooner, and hence reduce power consumption of the voltage translator circuit.

As described above, when node 130.1 rises from 0V to 3V, node 130.2 follows node 130.1 up to only 2V and has to wait for a while until pull-up PMOS transistor 150 turns on and pulls node 130.2 from 2V up to 5V. It takes a while for node 130.2 to reach a logic 1 (5V) after node 130.1 reaches a logic 1 (3V). Therefore, it is another object of the present invention to reduce the delay in transmitting a logic 1 from node 130.1 to node 130.2.

### SUMMARY OF THE INVENTION

The voltage translation circuit of the present invention (FIG. 3) achieves the stated objects by using a transmission PMOS transistor 200 in parallel with the transmission NMOS transistor 160. When node 140 rises from 0V to 3V (logic 1), this transmission PMOS transistor 200 helps to raise the voltage of the input to pull-up control CMOS inverter 170, 180 faster and therefore helps to turn on pull-up PMOS transistor 190 faster and hence raise the voltage of node 155 faster. This in turn helps turn off PMOS transistor 170 sooner, and hence stop the transition current going through transistors 170 and 180 sooner. Pull-up PMOS transistor 190 being turned on faster helps pull node 155 up to 5V (logic 1) faster. The gate of transmission PMOS transistor 200 is coupled to the gate of the pull-up PMOS transistor 190 via an transmission control CMOS inverter 300 so that when the pull-up PMOS transistor 190 is turned on, transmission PMOS transistor 200 will be turned off. This stops another transition current going through transistors 190 and 200.

### BRIEF DESCRIPTION OF THE DRAWINGS

FIG. 1 is an electrical schematic diagram showing a circuit portion of a voltage translation circuit of prior art.

FIG. 2 is an electrical schematic diagram showing an alternative view of the circuit portion of FIG. 1.

FIG. 3 is an electrical schematic diagram showing a first preferred embodiment of the voltage translation circuit of the present invention.

FIG. 4 is an electrical schematic diagram showing a second preferred embodiment of the voltage translation circuit of the present invention.

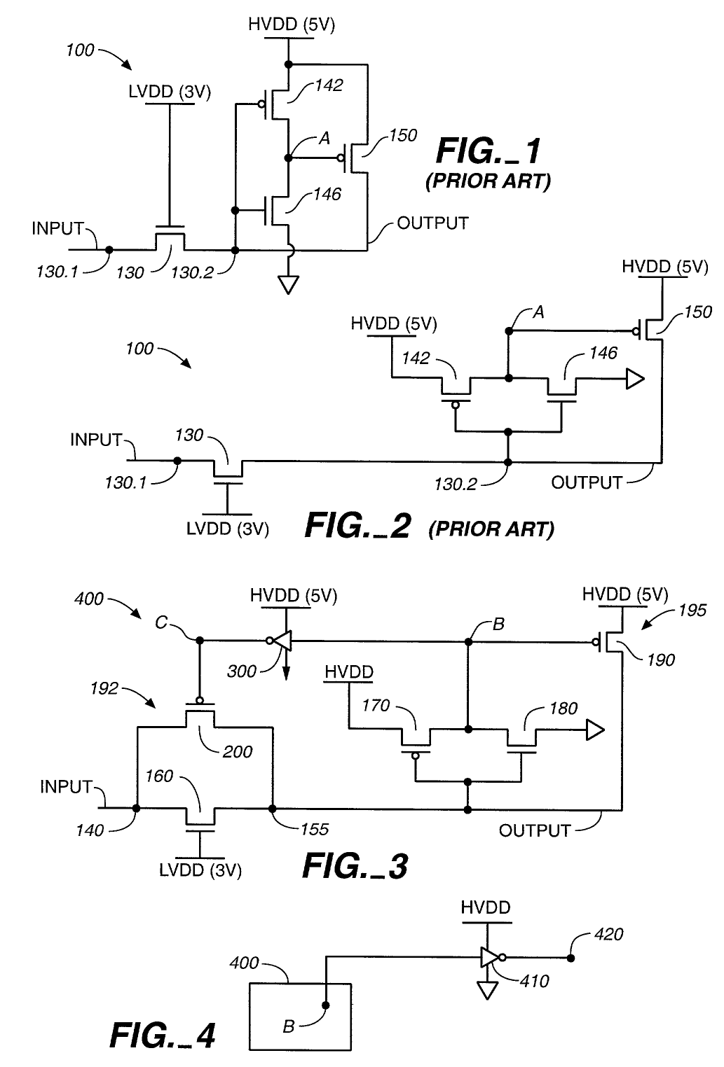

### BEST MODE FOR CARRYING OUT THE INVENTION

With reference to FIG. 3, the voltage translation circuit 400 of the present invention comprises a transmission PMOS transistor 200 in parallel with a transmission NMOS transistor 160. Each of transmission transistors 200 and 160 has one source/drain connected to node 140 and the other source/drain connected to node 155. The gate of transmission NMOS transistor 160 connects to 3V (LVDD, i.e., low VDD). The output of the first circuit (not shown) operating at 3V (LVDD) connects to node 140. In a first preferred embodiment of the present invention, node 155 connects to the input of the second circuit (not shown) operating at 5V (HVDD, i.e., high VDD). Transmission PMOS transistor 200 and transmission NMOS transistor 160 together form a transmission circuit 192. A bootstrap circuit 195 consists of a pull-up PMOS transistor 190 and a pull-up control CMOS inverter 170, 180. Pull-up control CMOS inverter 170,180 consists of an NMOS transistor 180 and a PMOS transistor 170. The input of pull-up control CMOS inverter 170,180 connects to node 155 and to the drain of pull-up PMOS transistor 190. The source of pull-up PMOS transistor 190 connects to 5V (HVDD). The output of pull-up control CMOS inverter 170,180 (node B) connects to the gate of pull-up PMOS transistor 190 and to the input of a transmission control CMOS inverter 300. The output of transmission control CMOS inverter 300 (node C) connects to the gate of transmission PMOS transistor 200. Transmission control CMOS inverter 300 forms a feedback path from bootstrap circuit 195 to transmission circuit 192.

This feedback path, when bootstrap circuit 195 starts pulling up the voltage of node 155, carries a shutoff transmission control signal from node B to transmission PMOS transistor 200 via transmission control CMOS inverter 300. This shutoff transmission control signal helps turn off transmission PMOS transistor 200, thereby shutting of the whole transmission circuit 192, because transmission NMOS transistor 160 is already off at this time as will be described in detail below.

Voltage translation circuit 400 in FIG. 3 fulfills the objects of the present invention by helping pull node 155 up faster to a voltage greater than 2V (i.e. LVDD−Vtn=a threshold voltage drop below the gate voltage of transmission NMOS transistor 160) and thereby turning on pull-up PMOS transistor 190 faster. This in turn pulls node 155 up to 5V faster and hence turning off PMOS transistor 170 faster and stopping the transition current through transistors 170 and 180 sooner.

With reference again to FIG. 3, when node 140 is 0V, transmission NMOS transistor 160 is on; node 155 is also 0V. Node B is 5V (HVDD). Node C is 0V. Transmission PMOS transistor 200 is off. Pull-up PMOS transistor 190 is also off.

When node 140 rises from 0V to 3V (LVDD), because transmission NMOS transistor 160 has been on, node 155 follows node 140 in voltage. However, when node 140 rises past the threshold voltage |Vtp| (i.e., 1V, assume Vtp=−1V) of transmission PMOS transistor 200, transmission PMOS transistor 200 turns on contributing with transmission NMOS transistor 160 in helping node 155 follow node 140 in voltage. While transmission NMOS transistor 160 only helps node 155 to follow node 140 up to 2V and then turns off because voltage difference between its gate [3V] and its source [>2V] is less than Vtn [1V], transmission PMOS transistor 200 continues to help node 155 follow node 140 up to 3V (LVDD). This in turn turns on NMOS transistor 180 faster than in the case of circuit portion 100 of FIG. 2 where node 130.2 follows node 130.1 up to only 2V.

Therefore, in voltage translation circuit 400 of the present invention (FIG. 3), pull-up PMOS transistor 190 is turned on faster. This in turn pulls node 155 up to 5V (HVDD, also a logic 1) faster. This also turns off PMOS transistor 170 faster and stops the transition current going through transistors 170 and 180 sooner.

There is only a small drawback to voltage translation circuit 400 of the present invention. When node 140 rises from 0V to 3V (LVDD), node 155 follows node 140 in voltage with the help of transmission circuit 192 as discussed above. Then, pull-up PMOS transistor 190 turns on pulling node 155 up to 5V. This forms a current path from HVDD (5V) to node 140 (3V) through pull-up PMOS transistor 190 and transmission PMOS transistor 200. However, because these two PMOS transistors 190 and 200 have their gates coupled to each other via transmission control CMOS inverter 300, if pull-up PMOS transistor 190 turns on, transmission PMOS transistor 200 will turn off with some delay due to signal propagation delay through transmission control CMOS inverter 300. With transmission PMOS transistor 200 being off, the current path is shut off. Therefore, the drawback to voltage translation circuit 400 of the present invention is only minor.

When node 140 goes from 3V down to 0V, transmission PMOS transistor 200 remains off all the way. Transmission NMOS transistor 160 turns on and pulls node 155 down. At some point, pull-up control CMOS inverter 170,180 changes state and node B becomes 5V turning off pull-up PMOS transistor 190. With pull-up PMOS transistor 190 being off, node 155 follows node 140 down to 0V.

Node B rising from 0V to 5V makes node C fall from 5V down to 0V. However, at this time, node 155 has fallen down close to 0V; therefore, transmission PMOS transistor 200 remains off.

In the first preferred embodiment of the present invention, node 155 connects to the input of the second circuit (not shown, but mentioned in background art section) operating at 5V (HVDD). A buffer can be added to couple node 155 and the input of the second circuit. In a second preferred embodiment, instead of connecting node 155 of voltage translation circuit 400 to the input of the second circuit (not shown) operating at HVDD (5V), node B can be used to connect to the input of the second circuit as shown in FIG. 4.

With reference to FIG. 4, an output CMOS inverter 410 can be used to invert the signal from node B, and an output 420 of output CMOS inverter 410 connects to the input of the second circuit (not shown). Output CMOS inverter 410 can be designed to handle any load required by the second circuit.

Other nodes of voltage translation circuit 400 can be used to interface with the input of the second circuit (not shown). For instance, node C can be used, with some additional delay because now the propagation of logic values has to go from the output of the first circuit (i.e., node 140) operating at LVDD (3V) through pull-up control CMOS inverter 170,180 and transmission control CMOS inverter 300 to the input of the second circuit (i.e., node C) operating at HVDD (5V).

The use of voltage levels of 0V, 3V, and 5V to represent logic 0 (0V) and logic 1 (3V and 5V) is just for illustrative purposes. The voltage translation circuit of the present invention can be used to interface circuits operating at any voltage levels. Moreover, CMOS inverters are also used for illustration. Any other type of inverters can also be used in the present invention.

1. A voltage translation circuit comprising:
a first node for receiving a first signal switching between first and second voltage levels, said second voltage level being greater than said first voltage level;
a second node for outputting a second signal switching between said first voltage level and a third voltage level, said third voltage level being greater than said second voltage level;
a transmission subcircuit for connecting said first node and said second node and for transmitting said first signal from said first node to said second node such that when the voltage of said first node rises from said first voltage level up to but not over said second voltage level, said transmission subcircuit having means for forcing said second node to follow said first node in voltage, said transmission subcircuit having a third node for receiving a shutoff transmission control signal to turn off said transmission subcircuit and thereby decouple said first node and said second node;
a bootstrap subcircuit having a fourth node connected to said second node via a first path for pulling via said first path the voltage of said second node up to said third voltage level whenever the voltage of said second node rises substantially close to said second voltage level, said bootstrap subcircuit also having a fifth node for outputting said shutoff transmission control signal to said transmission subcircuit via a feedback path in response to said bootstrap subcircuit starting the pulling of the voltage of said second node up to said third voltage level, said feedback path connecting said fifth node and said third node.

2. The voltage translation circuit of claim 1 wherein said transmission subcircuit further comprises:
a transmission control element and
a transmission element, said transmission control element being electrically connected to said third node directly and to said transmission element via a second path, said transmission element electrically coupling said first node and said second node, such that when said bootstrap subcircuit pulls said second node up to said third voltage level, said bootstrap subcircuit via said feedback path triggers said transmission control element to control said transmission element via said second path to decouple said first node and said second node.

3. The voltage translation circuit of claim 2 wherein said transmission control element further comprises at least a first inverter having a first input connected to said third node, and a first output connected to said second path.

4. The voltage translation circuit of claim 3 wherein said first inverter is a CMOS inverter.

5. The voltage translation circuit of claim 4 wherein said transmission element further comprises first and second transistors, said first transistor having a first source/drain connected to said first node and a second source/drain connected to said second node, and a first gate connected to said transmission control element via said second path, said second transistor having a third source/drain connected to said first node and a fourth source/drain connected to said second node, and a second gate having said second voltage level.

6. The voltage translation circuit of claim 5 wherein said first transistor is a PMOS transistor and said second transistor is an NMOS transistor.

7. The voltage translation circuit of claim 3 wherein said transmission element further comprises first and second transistors, said first transistor having a first source/drain connected to said first node and a second source/drain connected to said second node, and a first gate connected to said transmission control element via said second path, said second transistor having a third source/drain connected to said first node and a fourth source/drain connected to said second node, and a second gate having said second voltage level.

8. The voltage translation circuit of claim 7 wherein said first transistor is a PMOS transistor and said second transistor is an NMOS transistor.

9. The voltage translation circuit of claim 2 wherein said transmission element further comprises first and second transistors, said first transistor having a first source/drain connected to said first node and a second source/drain connected to said second node, and a first gate connected to said transmission control element via said second path, said second transistor having a third source/drain connected to said first node and a fourth source/drain connected to said second node, and a second gate having said second voltage level.

10. The voltage translation circuit of claim 9 wherein said first transistor is a PMOS transistor and said second transistor is an NMOS transistor.

11. The voltage translation circuit of claim 2 wherein said bootstrap subcircuit further comprises:
a pull-up element and
a pull-up control element, said pull-up element being electrically connected to said pull-up control element via a third path and to said fourth node via a fourth path, said pull-up control element being electrically connected to said fourth node via a fifth path, said third path being connected to said fifth node, such that when said transmission subcircuit makes said second node follow said first node up to said second voltage level, said pull-up control element is triggered via said first path and said fifth path to control said pull-up element via said third path to pull said second node up to said third voltage level via said fourth path and said first path.

12. The voltage translation circuit of claim 11 wherein said pull-up element further comprises at least a third transistor having a fifth source/drain having said third voltage level, a sixth source/drain connected to said fourth path, and a third gate connected to said third path.

13. The voltage translation circuit of claim 12 wherein said third transistor is a PMOS transistor.

14. A voltage translation circuit comprising:
a transmission element for transmitting a first and second voltage levels from a first node to a second node, said second voltage level being greater than said first voltage level, said transmission element having a third node;
a bootstrap subcircuit for raising the voltage at said second node to a third voltage level whenever the voltage at said second node rises from said first voltage level to said second voltage level, said third voltage level being greater than said second voltage level, said bootstrap subcircuit having fourth and fifth nodes, said fourth node being connected to said second node; and
transmission control element for turning off the operation of said transmission element whenever the voltage at said second node rises substantially close to said third voltage level, said transmission control element having sixth and seventh nodes, said sixth node being connected to said fifth node, said seventh node being connected to said third node.

15. The voltage translation circuit of claim 14 wherein said transmission element further comprises first and second transistors, said first transistor having a first source/drain connected to said first node and a second source/drain connected to said second node, and a first gate connected to said third node, said second transistor having a third source/drain connected to said first node and a fourth source/drain connected to said second node, and a second gate having said second voltage level.

16. The voltage translation circuit of claim 15 wherein said first transistor is a PMOS transistor and said second transistor is an NMOS transistor.

17. The voltage translation circuit of claim 16 wherein said transmission control element further comprises at least a first inverter having a first input connected to said sixth node, and a first output connected to said seventh node.

18. The voltage translation circuit of claim 17 wherein said first inverter is a CMOS inverter.

19. The voltage translation circuit of claim 15 wherein said transmission control element further comprises at least a first inverter having a first input connected to said sixth node, and a first output connected to said seventh node.

20. The voltage translation circuit of claim 19 wherein said first inverter is a CMOS inverter.
